(19) United States
(12) Patent Application Publication
(10) Pub. No.: US 2023/0314927 A1
(43) Pub. Date: Oct. 5, 2023

(54) EUV PHOTO MASKS AND MANUFACTURING METHOD THEREOF

(71) Applicant: TAIWAN SEMICONDUCTOR MANUFACTURING COMPANY, LTD., Hsinchu (TW)

(72) Inventors: Sheng-Min WANG, New Taipei City (TW); Yu-Tse LAI, Zhubei City (TW); Ken-Hsien HSIEH, Taipei City (TW)

(21) Appl. No.: 17/833,830

(22) Filed: Jun. 6, 2022

Related U.S. Application Data
(60) Provisional application No. 63/327,521, filed on Apr. 5, 2022.

(51) Int. Cl. G03F 1/24; G03F 1/76

(52) U.S. Cl. CPC G03F 1/24; G03F 1/76

(57) ABSTRACT

A photo mask for an extreme ultraviolet (EUV) lithography includes a circuit pattern, and sub-resolution assist patterns disposed around and connected to the circuit pattern. A dimension of the sub-resolution assist patterns is in a range from 10 nm to 50 nm.

### RELATED APPLICATION

This application claims priority to U.S. Provisional Patent Application No. 63/327,521 filed Apr. 5, 2022, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). The photo mask is an important component in photolithography operations. It is critical to fabricate EUV photo masks having a high contrast with a high reflectivity part and a high absorption part.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show an EUV reflective photo mask according to an embodiment of the present disclosure.

FIGS. 2A, 2B, 2C, 2D, 2E and 2F schematically illustrate a method of fabricating an EUV photo mask according to an embodiment of the present disclosure.

FIGS. 3A, 3B, 3C and 3D schematically illustrate a method of fabricating an EUV photo mask according to an embodiment of the present disclosure.

FIG. 4A shows a plan view of an EUV photo mask according to an embodiment of the present disclosure. FIG. 4B shows a cross sectional view of an EUV photo mask according to embodiments of the present disclosure.

FIG. 5 shows simulation or calculation results showing background intensity suppression by sub-resolution patterns according to embodiments of the present disclosure.

FIGS. 6A, 6B and 6C show plan views of mask patterns according to embodiments of the present disclosure.

FIGS. 7A and 7B show sub-resolution assist feature layouts according to embodiments of the present disclosure.

FIG. 8A is a plan view (layout view) and FIGS. 8B, 8C, 8D and 8E show cross sectional views corresponding to line X1, line X2, line Y1 and line Y2 of FIG. 8A, respectively, of an EUV photo mask according to an embodiment of the present disclosure. FIG. 8F shows a cross sectional view corresponding to line Y2 of FIG. 8A of an EUV photo mask according to an embodiment of the present disclosure.

FIG. 9 illustrate various sub-resolution assist features according to embodiments of the present disclosure.

FIGS. 10A and 10B show a photo mask data generating apparatus according to an embodiment of the present disclosure.

FIG. 11A shows a flowchart of a method making a semiconductor device, and FIGS. 11B, 11C, 11D and 11E show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Materials, configurations, processes and/or dimensions as explained with respect to one embodiment may be employed in other embodiments and detailed description thereof may be omitted. In the present disclosure, a reticle, a photo mask, or a mask are interchangeable used.

Embodiments of the present disclosure provide a method of manufacturing an EUV photo mask. EUV lithography (EUVL) employs scanners using light in the extreme ultraviolet (EUV) region, having a wavelength of about 1 nm to about 100 nm, for example, 13.5 nm. The mask is a critical component of an EUVL system. Because the optical materials are not transparent to EUV radiation, EUV photo masks are reflective masks. Circuit patterns are formed in an absorber layer disposed over the reflective structure.

EUV masks includes a binary mask and a phase shift mask, and the phase shift mask includes an alternating phase shift mask and an attenuated phase shift mask (APSM). In the APSM, some of light blocking patterns (absorber layer) are made semi-transparent or semi-reflective, causing a 180 degree phase change. In some embodiments, the absorber layer of the EUV APSM includes a low-n and low-k EUV absorbing layer having a refractive index n less than about 0.95 (and more than about 0.8) and an absorption coefficient k less than about 0.04 (and more than about 0.005) for the EUV light (e.g., 13.5 nm). In some embodiments, the reflectivity of the absorber layer 25 is equal to or greater than about 5% (and less than about 20%). In such, a high-reflectance APSM may cause random printouts on the photo resist layer from the board absorber pattern as a background light. In the present disclosure, sub-resolution assist features (SRAFs) are utilized to suppress the background light from the absorber patterns.

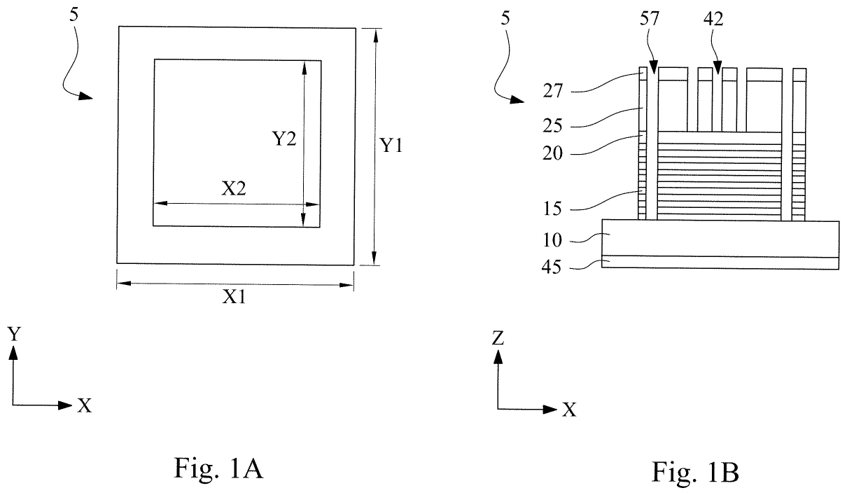

FIGS. 1A and 1B show an EUV reflective photo mask according to an embodiment of the present disclosure. FIG. 1A is a plan view (viewed from the top) and FIG. 1B is a cross sectional view.

In some embodiments, the EUV photo mask 5 includes a substrate 10, a multilayer Mo/Si stack 15 of multiple alternating layers of silicon and molybdenum, a capping layer 20 and an absorber layer 25. In some embodiments, an antireflective layer 27 is optionally disposed over the absorber layer 25. Further, a backside conductive layer 45 is formed on the backside of the substrate 10, as shown in FIG. 1B.

The substrate 10 is formed of a low thermal expansion material in some embodiments. In some embodiments, the substrate 10 is a low thermal expansion glass or quartz, such as fused silica or fused quartz. In some embodiments, the low thermal expansion glass substrate transmits light at visible wavelengths, a portion of the infrared wavelengths near the visible spectrum (near infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size X1×Y1 of the substrate 10 is about 152 mm×about 152 mm having a thickness of about 20 mm. In other embodiments, the size of the substrate 10 is smaller than 152 mm×152 mm and equal to or greater than 148 mm×148 mm. The shape of the substrate 10 is square or rectangular in some embodiments.

In some embodiments, the functional layers above the substrate (the multilayer Mo/Si stack 15, the capping layer 20, the absorber layer 25 and the cover layer 27 have a smaller width than the substrate 10. In some embodiments, the size X2×Y2 of the functional layers is in a range from about 138 mm×138 mm to 142 mm×142 mm. The shape of the functional layers is square or rectangular in some embodiments. In other embodiments, the absorber layer 25 and the cover layer 27 have a smaller size in the range from about 138 mm×138 mm to about 142 mm×142 mm than the substrate 10, the multilayer Mo/Si stack 15 and the capping layer 20. The smaller size of one or more of the functional layers can be formed by using a frame shaped cover having an opening in a range from about 138 mm×138 mm to about 142 mm×142 mm, when forming the respective layers by, for example, sputtering. In other embodiments, all of the layers above the substrate 10 have the same size as the substrate 10.

In some embodiments, the Mo/Si multilayer stack 15 includes from about 30 to 60 alternating pairs of silicon and molybdenum layers. In certain embodiments, the number of pairs is about 40 to about 50. In some embodiments, the reflectivity is higher than about 70% for the wavelengths of interest e.g., 13.5 nm. In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm, and the thickness of each molybdenum layer is about 3 nm. In some embodiments, the bottommost layer of the multilayer stack 15 is a Si layer or a Mo layer.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for the wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer stack 15 to prevent oxidation of the multilayer stack 15 in some embodiments. In some embodiments, the capping layer 20 is made of elemental ruthenium (more than 99% Ru, not a Ru compound), a ruthenium alloy (e.g., RuNb, RuZr, RuZrN, RuRh, RuNbN, RuRhN, RuV, RuVN, Rulr, RuTi, RuB, RuP, RuOs, RuPd RuPt or RuRe) or a ruthenium based oxide (e.g., RuO₂, RuNbO, RuVO or RuON), having a thickness of from about 2 nm to about 10 nm. In some embodiments, the capping layer 20 is a ruthenium compound RuₓM₁₋ₓ, where M is one or more of Nb, Jr, Rh, Zr, Ti, B, P, V, Os, Pd, Pt or Re, and x is more than zero and equal to or less than about 0.5

In certain embodiments, the thickness of the capping layer 20 is from about 2 nm to about 5 nm. In some embodiments, the capping layer 20 has a thickness of 3.5 nm±10%. In some embodiments, the capping layer 20 is formed by chemical vapor deposition, plasma-enhanced chemical vapor deposition, atomic layer deposition, physical vapor deposition (e.g., sputtering), or any other suitable film forming method. In other embodiments, a Si layer is used as the capping layer 20. One or more layers are disposed between the capping layer and the multilayer 15 as set forth below in some embodiments.

In some embodiments, the capping layer 20 includes two or more layers of different materials. In some embodiments, the capping layer 20 includes two or more layers of different Ru based materials. In some embodiments, the capping layer 20 includes two layers, a lower layer and an upper layer, and the upper layer has a higher carbon absorption resistance than the lower layer, and the lower layer has a higher etching resistance during the absorber etching. In certain embodiments, the capping layer 20 includes a RuNb based layer (RuNb or RuNbN) disposed on a RuRh based layer (RuRh or RuRhN).

The absorber layer 25 is disposed over the capping layer 20. The absorber layer 25 includes one or more layers having a high EUV absorption. In some embodiments, the absorber layer 25 is Ta based material. In some embodiments, the absorber layer 25 is made of TaN, TaO, TaB, TaBO or TaBN. In some embodiments, the absorber layer 25 has a multilayered structure of TaN, TaO, TaB, TaBO or TaBN. In other embodiments, the absorber layer 25 includes a Cr based material, such as CrN, CrBN, CrO and/or CrON. In some embodiments, the absorber layer 25 has a multilayered structure of Cr, CrO or CrON. In some embodiments, the absorber layer is Jr or an Jr based material, such as, IrRu, IrPt, IrN, IrAl, IrSi or IrTi. In some embodiments, the absorber layer is a Ru based material, such as, IrRu, RuPt, RuN, RuAl, RuSi or RuTi, or a Pt based material, Par, RuPt, PtN, PtAl, PtSi or PtTi. In other embodiments, the absorber layer includes an Os based material, a Pd based material, or a Re based material. In some embodiments of the present disclosure, an X based material means that an amount of X is equal to or more than 50 atomic %. In other embodiments, the absorber layer material is represented by AₓB_{y}, where A and B are each one or more of W, Jr, Pt, Ru, Cr, Ta, Os, Pd, Al or Re, and x:y is from about 0.25:1 to about 4:1. In some embodiments, xis different from y (smaller or larger). In some embodiments, the absorber layer further includes one or more of Si, B, or N in an amount of more than zero to about 10 atomic %.

In some embodiments, the thickness of the absorber layer 25 ranges from about 10 nm to about 100 nm, and ranges from about 25 nm to about 75 nm in other embodiments. In some embodiments, the absorber layer 25 is formed by chemical vapor deposition, plasma-enhanced chemical vapor deposition, atomic layer deposition, physical vapor deposition, or any other suitable film forming method. One or more layers are disposed between the capping layer 20 and the absorber layer 25 as set forth below in some embodiments.

In some embodiments, a cover or antireflective layer 27 is disposed over the absorber layer 25. In some embodiments, the cover layer 27 includes a Ta based material, such as TaB, TaO or TaBO, silicon, a silicon based compound (e.g., silicon oxide, SiN, SiON or MoSi), ruthenium, or a ruthenium based compound (Ru or RuB). In certain embodiments, the cover layer 27 is made of tantalum oxide (Ta₂O₅ or non-stoichiometric (e.g., oxygen deficient) tantalum oxide), and has a thickness of from about 2 nm to about 20 nm. In other embodiments, a TaBO layer having a thickness in a range from about 2 nm to about 20 nm is used as the cover layer. In some embodiments, the thickness of the cover layer 27 is from about 2 nm to about 5 nm. In some embodiments, the cover layer 27 is formed by chemical vapor deposition, plasma-enhanced chemical vapor deposition, atomic layer deposition, physical vapor deposition, or any other suitable film forming method.

In some embodiments, the backside conductive layer 45 is disposed on a second main surface of the substrate 10 opposing the first main surface of the substrate 10 on which the Mo/Si multilayer stack 15 is formed. In some embodiments, the backside conductive layer 45 is made of TaB (tantalum boride) or other Ta based conductive material. In some embodiments, the tantalum boride is crystalline. The crystalline tantalum boride includes TaB, Ta₅B₆, Ta₃B₄ and TaB₂. In other embodiments, the tantalum boride is poly crystalline or amorphous. In other embodiments, the backside conductive layer 45 is made of a Cr based conductive material (CrN or CrON). In some embodiments, the sheet resistance of the backside conductive layer 45 is equal to or smaller than 20 Ω/□. In certain embodiments, the sheet resistance of the backside conductive layer 45 is equal to or more than 0.1 Ω/□. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm. In some embodiments, the flatness of the backside conductive layer 45 is more than 1 nm. A thickness of the backside conductive layer 45 is in a range from about 50 nm to about 400 nm in some embodiments. In other embodiments, the backside conductive layer 45 has a thickness of about 50 nm to about 100 nm. In certain embodiments, the thickness is in a range from about 65 nm to about 75 nm. In some embodiments, the backside conductive layer 45 is formed by atmospheric chemical vapor deposition (CVD), low pressure CVD, plasma-enhanced CVD, laser-enhanced CVD, atomic layer deposition (ALD), molecular beam epitaxy (MBE), physical vapor deposition including thermal deposition, pulsed laser deposition, electron-beam evaporation, ion beam assisted evaporation and sputtering, or any other suitable film forming method. In cases of CVD, source gases include TaCl₅ and BCl₃ in some embodiments.

As shown in FIG. 1B, the EUV photo mask 5 includes a circuit pattern 42 in the circuit pattern area and a black border 57 surrounding the circuit pattern area.

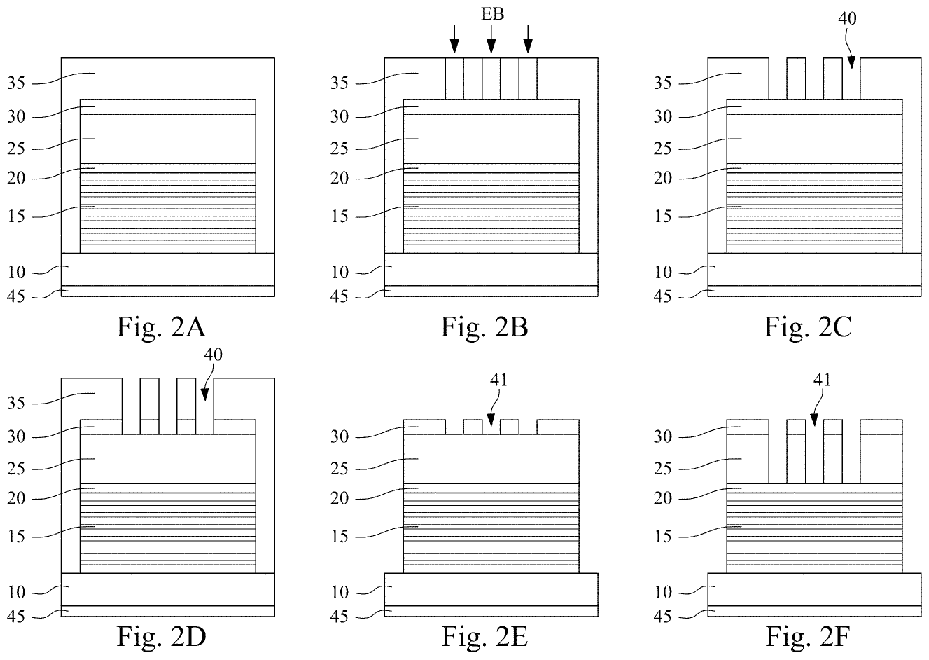

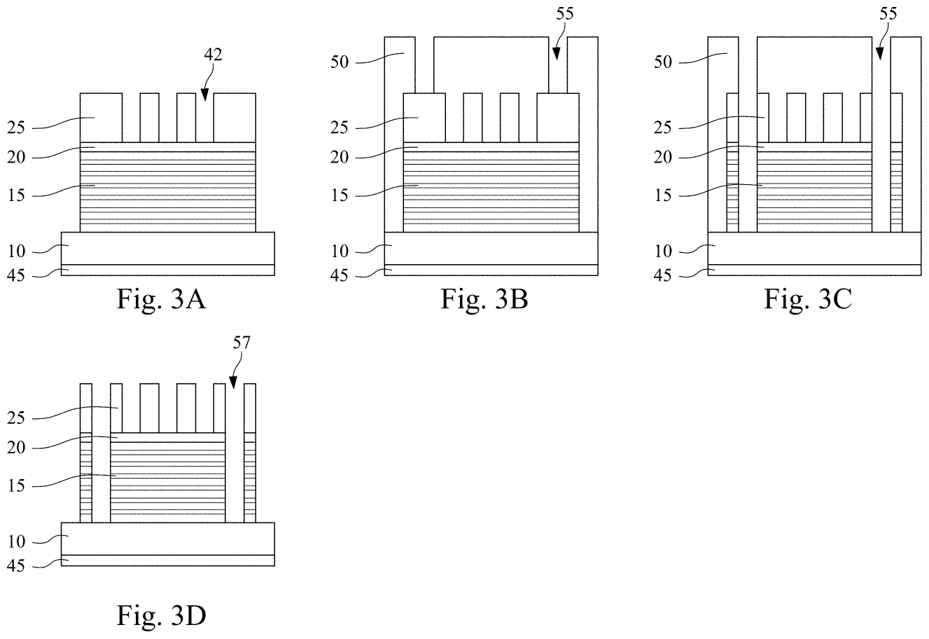

FIGS. 2A-2F and 3A-3D schematically illustrate a method of fabricating an EUV photo mask for use in extreme ultraviolet lithography (EUVL). It is understood that additional operations can be provided before, during, and after processes shown by FIGS. 2A-3D, and some of the operations described below can be replaced or eliminated for additional embodiments of the method. The order of the operations/processes may be interchangeable.

In the fabrication of an EUV photo mask, a first photoresist layer 35 is formed over the hard mask layer 30 of the EUV photo mask blank as shown in FIG. 2A, and the photoresist layer 35 is selectively exposed to actinic radiation EB as shown in FIG. 2B. Before the first photoresist layer 35 is formed, the EUV photo mask blank is subject to inspection in some embodiments. The selectively exposed first photoresist layer 35 is developed to form a pattern 40 in the first photoresist layer 35 as shown in FIG. 2C. In some embodiments, the actinic radiation EB is an electron beam or an ion beam. In some embodiments, the pattern 40 corresponds to a pattern of semiconductor device features for which the EUV photo mask will be used to form in subsequent operations.

Next, the pattern 40 in the first photoresist layer 35 is extended into the hard mask layer 30 forming a pattern 41 in the hard mask layer 30 exposing portions of the absorber layer 25, as shown in FIG. 2D. The pattern 41 extended into the hard mask layer 30 is formed by etching, in some embodiments, using a suitable wet or dry etchant that is selective to the absorber layer 25. After the pattern 41 in the hard mask layer 30 is formed, the first photoresist layer 35 is removed by a photoresist stripper to expose the upper surface of the hard mask layer 30, as shown in FIG. 2E.

Then, the pattern 41 in the hard mask layer 30 is extended into the absorber layer 25 forming a pattern 42 in the absorber layer 25 exposing portions of the capping layer 20, as shown in FIG. 2F, and then the hard mask layer 30 is removed as shown in FIG. 3A. The pattern 42 extended into the absorber layer 25 is formed by etching, in some embodiments, using a suitable wet or dry etchant that is selective to the absorber layer 25. In some embodiments, plasma dry etching is used.

As shown in FIG. 3B, a second photoresist layer 50 is formed over the absorber layer 25 filling the pattern 42 in the absorber layer 25. The second photoresist layer 50 is selectively exposed to actinic radiation such as electron beam, ion beam or UV radiation. The selectively exposed second photoresist layer 50 is developed to form a pattern 55 in the second photoresist layer 50 as shown in FIG. 3B. The pattern 55 corresponds to a black border surrounding the circuit patterns. A black border is a frame shape area created by removing all the multilayers on the EUV photo mask in the region around a circuit pattern area. It is created to prevent exposure of adjacent fields when printing an EUV photo mask on a wafer. The width of the black border is in a range from about 1 mm to about 5 mm in some embodiments.

Next, the pattern 55 in the second photoresist layer 50 is extended into the absorber layer 25, capping layer 20, and Mo/Si multilayer 15 forming a pattern 57 (see, FIG. 3D) in the absorber layer 25, capping layer 20, and Mo/Si multilayer 15 exposing portions of the substrate 10, as shown in FIG. 3C. The pattern 57 is formed by etching, in some embodiments, using one or more suitable wet or dry etchants that are selective to each of the layers that are etched. In some embodiments, plasma dry etching is used.

Then, the second photoresist layer 50 is removed by a suitable photoresist stripper to expose the upper surface of the absorber layer 25 as shown in FIG. 3D. The black border pattern 57 in the absorber layer 25, capping layer 20, and the Mo/Si multilayer 15 defines a black border of the photo mask in some embodiments of the disclosure.

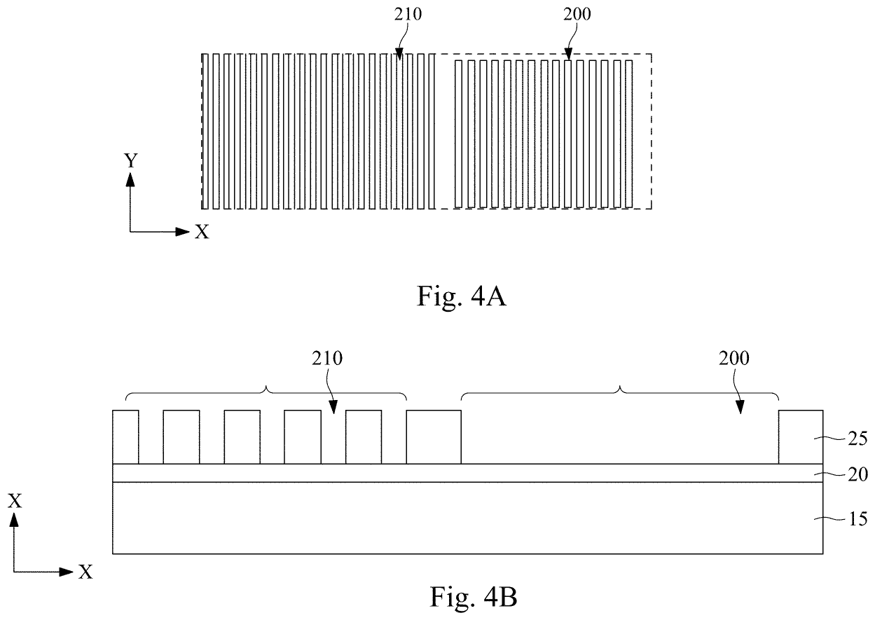

FIG. 4A is a plan view or a layout view of an EUV photo mask and FIG. 4B is a cross sectional view thereof according to an embodiment of the present disclosure.

In some embodiments, the EUV photo mask includes circuit patterns 200 as grooves, trenches or openings formed in the absorber layer 25. In some embodiments, the dimension (e.g., width) of the circuit patterns 200 is equal to or more than 40 nm on the 4× mask.

In some embodiments, the EUV photo mask further includes a plurality of sub-resolution assist features (SRAFs) 210 formed in the absorber layer 25, as shown in FIGS. 4A and 4B. In some embodiments, when the photo mask is a 4× mask, the SRAF 210 includes a grating, such as periodical patterns having a pitch equal to or more than about 20 nm and less than about 160 nm, and in a range from about 40 nm to about 120 nm in other embodiments. When the photo mask is a 5× mask, the SRAF 210 includes periodical patterns having a pitch in a range from about 25 nm to about 200 nm, and in a range from about 50 nm to about 150 nm in other embodiments. In other words, the pitch of the periodical patterns on the wafer is about 5 nm or more and less than about 40 nm. In some embodiments, the SRAF 210 includes periodical line and space patterns having the aforementioned pitch(es), and the width of the line pattern is equal to or more than about 4 nm and less than 160 nm on the 4× mask, and is in a range from about 10 nm to about 80 nm in other embodiments. In some embodiments, the width of the SRAF pattern 210 is about 1/10 to about ⅕ of the minimum line width of the circuit patterns. In some embodiments, a ratio of the line width to the pitch (aspect ratio) is in a range from about 0.1 to about 0.9. The SRAF patterns 210 are not printable as a photo resist pattern over the substrate.

When the pitch of the SRAF patterns 210 is sufficiently small, the ±1 or higher diffraction patterns do not enter the pupil (aperture) of the EUV lithography tool, and thus the light reflected at the absorber layer does not cause random printout on the photo resist layer.

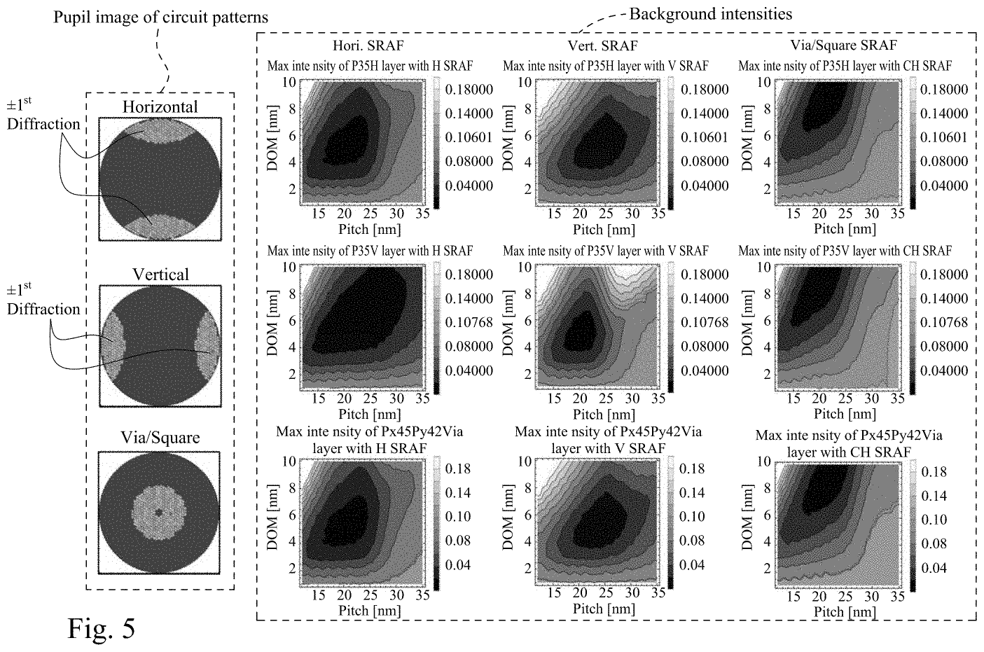

FIG. 5 shows the effects of the SRAF patterns. FIG. 5 shows pupil images of main circuit patterns having periodic line patterns or a via (square) pattern, and the background intensity with SRAF patterns. In some embodiments, the “Horizontal” corresponds to the first periodic line patterns extending in the X direction and arranged in parallel with each other in the Y direction, the “Vertical” corresponds to the periodic line patterns extending in the X direction and arranged in parallel with each other in the X direction, and “Via/Square” corresponds to a square pattern. In the background intensity diagrams, the horizontal axis shows a pitch of the SRAF and the vertical axis shows a width of the line pattern of the SRAF, and the darker regions indicate lower background intensities. As shown in FIG. 5, it is possible to effectively suppress the background intensity (the reflected EUV light) by adjusting the pitch and/or line width of the SRAF patterns. Thus, the SRAF patterns are background intensity suppression patterns.

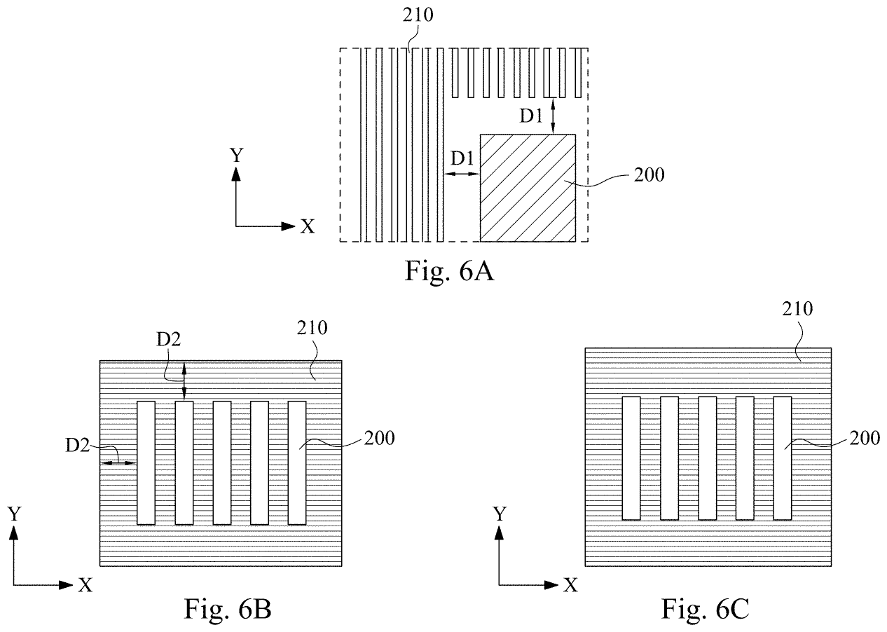

In some embodiments, the SRAF patterns 210 surround the circuit patterns 200 separated by a distance, and thus the SRAF patterns 210 are separated from the circuit patterns 200, as shown in FIG. 6A. In FIG. 6A, the SRAF 210 includes line-and-space patterns periodically arranged in one direction (X) . The line-and-space patterns have a width and a pitch as set forth above. As shown in FIG. 6A, the SRAF patterns 210 are separated from the circuit pattern 200 by a distance D1, which is in a range from about 10 nm to 100 nm on a photo mask in some embodiments.

In other embodiments, the SRAF patterns 210 are connected to the circuit patterns 200, thereby forming a continuous groove pattern. FIGS. 6B and 6C show SRAF patterns according to various embodiments of the present disclosure. In some embodiments, the circuit patterns 200 include line-and-space patterns extending in the Y direction and arranged in the X direction. In some embodiments, as shown in FIG. 6B, the SRAF 210 includes line-and-space patterns extending in the X direction and arranged in the Y direction, i.e., perpendicular to the line-and-space patterns 200. In other embodiments, as shown in FIG. 6C, the SRAF 210 includes line-and-space patterns extending in the Y direction and arranged in the X direction, i.e., parallel to the line-and-space patterns 200.

In some embodiments, the SRAF patterns 210 are provided in the area surrounding the circuit patterns. In some embodiments, the distance D2 between the outermost edges of the circuit patterns 200 in the X direction and the Y direction to the outer periphery of the SRAF pattern area is in a range from about 4000 nm to 40,000 nm on the photo mask. The non-patterned absorber layer is present outside this area in some embodiments.

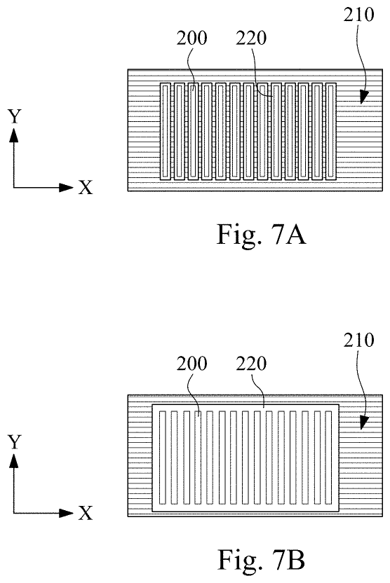

In some embodiments, as shown in FIG. 7A, each of the line patterns of the circuit pattern 200 is surrounded by a margin area (space) 220, which corresponds to the absorber layer. The width of the margin area 220 (a distance between the circuit pattern 200 and the SRAF pattern 210) is in a range from about 10 nm to 100 nm on the photo mask in some embodiments.

In other embodiments, as shown in FIG. 7B, a group of the line-and-space patterns are surrounded by the margin area 220. The distance between the group of line patterns 200 and the SRAF pattern 210 is in a range from about 10 nm to 100 nm on the photo mask in some embodiments.

In some embodiments, the SRAF patterns are provided for large absorber areas. In some embodiments, the SRAF patterns are generated by a photo mask data generating apparatus such that no absorber pattern equal to or greater than the threshold size exists. In some embodiments, the threshold size is in a range from about 100 nm² to about 250,000 nm² on the mask and is in a range from about 2500 nm² to about 10,000 nm² in other embodiments.

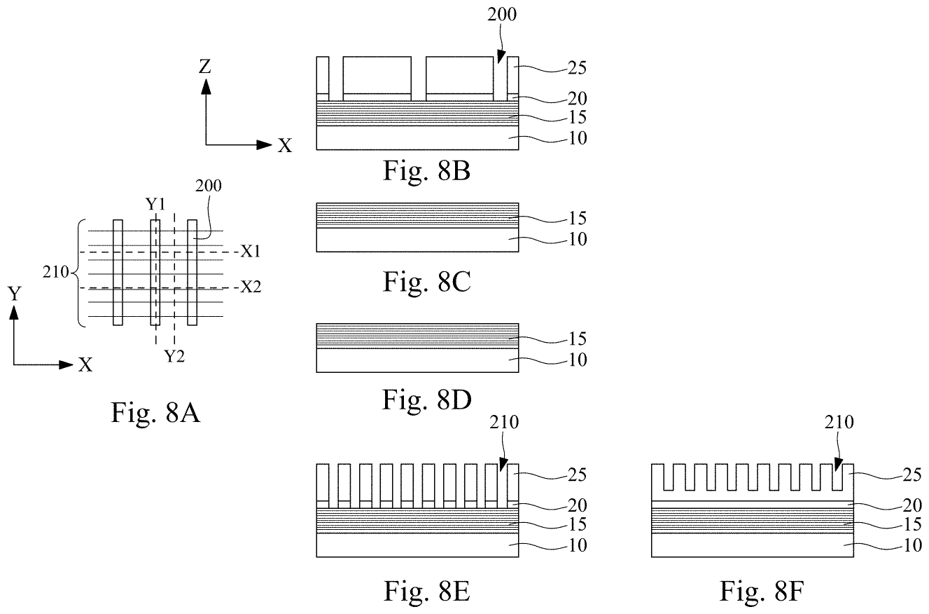

FIGS. 8A-8E shows various view of the structure of the EUV photo mask with SRAF patterns according to an embodiment of the present disclosure. FIG. 8A is a plan view (layout view), FIGS. 8B, 8C, 8D and 8E show cross sectional views corresponding to line X1, line X2, line Y1 and line Y2, respectively. As shown in FIGS. 8A-8E, the circuit pattern includes line patterns 200 as trenches formed in the absorber layer 25 and the capping layer 20, and the SRAF also includes line patterns 210 as trenches formed in the absorber layer 25 and the capping layer 20.

In some embodiments, as shown in FIGS. 8E and 8F, while the circuit pattern 200 is formed as openings in which the reflective multilayer structure 15 is exposed as shown in FIG. 8B, the SRAF patterns 210 are formed as openings of which the bottoms are located in the middle of the absorber layer 25. In some embodiments, since the opening widths between the circuit patterns 200 are sufficiently greater than the widths of the opening of the SRAF patterns 210, when the etching operation of the circuit patterns finishes (exposing the reflective multilayer 15 plus an additional over-etching), the etching of the SRAF patterns are still in progress. By stopping the etching at an appropriate timing, it is possible to obtain the structure shown in FIGS. 8B and 8F. In some embodiments, the depths of the openings of the SRAF patterns are about 40% to 90% of the thickness of the absorber layer 25. In some embodiments, the depths of the openings of the SRAF patterns are not uniform, and the variation of the depths (max to min) are in a range from about 1 nm to about 10 nm.

The circuit patterns 200 and the SRAF pattern 210 are formed at the same time (continuously) by e-beam lithography in some embodiments. In other embodiments, after or before the circuit patterns are exposed by electron beam, the SRAF patterns are exposed on the same photo resist layer. In other embodiments, before or after the circuit patterns are formed by electron beam lithography and etching operations, another photo resist layer is formed over the photo mask, and then an electron beam lithography or other lithography operations (optical, laser interference, etc.) are performed to form the SRAF patterns.

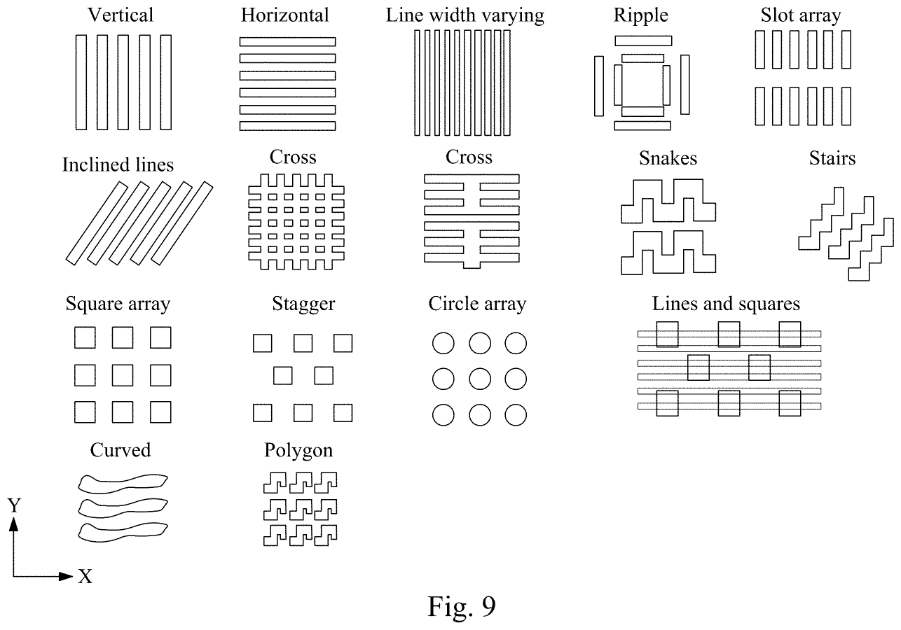

FIG. 9 shows various patterns for the SRAF according to embodiments of the present disclosure. In FIG. 9, the dark patterns correspond to reflective patterns (no absorber) and the background corresponds to the absorber layer (or substrate).

In some embodiments, the SRAF patterns are grating patterns. In some embodiments, the SRAF patterns are simple line-and-space patterns with a constant pitch extending in the X direction (horizontal) or the Y direction (vertical). In other embodiments, the pitch varies. In some embodiments, the pitch decreases as the distance to the circuit pattern decreases. In other embodiments, the pitch increases as the distance to the circuit pattern increases. In some embodiments, the pitch randomly changes. When the pitch randomly changes, the average pitch thereof is equal to or more than about 40 nm and less than about 160 nm.

In some embodiments, line width of the line patterns varies. In some embodiments, the width decreases as the distance to the circuit pattern decreases. In other embodiments, the width increases as the distance to the circuit pattern increases. In some embodiments, the width randomly changes. When the width randomly changes, the average width thereof is in a range from about 10 nm to about 50 nm.

In some embodiments, the line patterns of the SRAF patterns are segmented (cut into pieces) as a slot array.

In some embodiments, the SRAF patterns include a combination of the vertical patterns and the horizontal patterns.

In some embodiments, the line patterns of the SRAF are inclined with respect to the X or Y direction (pattern extending direction of the circuit patterns). In some embodiments, the inclination angle with respect to the X or Y direction is about 10 degrees to about 80 degrees.

In some embodiments, the SRAF patterns include ripple patterns which include vertical patterns arranged in parallel with longitudinal sides of vertically or horizontally extending circuit patterns and horizontal patterns arranged in parallel with the latitudinal sides thereof.

In some embodiments, the SRAF patterns include an array or matrix of square or circular patterns. In some embodiments, the matrix is a regular matrix and in other embodiments, the matrix is a staggered matrix. The pitches in the X direction and/or the Y direction are constant in some embodiments and varies in other embodiments similar to the line patterns as set forth above.

In some embodiments, the SRAF patterns include zig-zag patterns such as a snake pattern, a crank pattern, and a stair pattern.

In some embodiments, one or more sides of the SRAF pattern is curved. In some embodiments, the SRAF pattern is a concave or convex polygon other than a rectangle.

In some embodiments, the SRAF patterns include any combination of the aforementioned patterns.

In some embodiments, the SRAF patterns are layout patterns (e.g., patterns as GDS layout data) overlaps the circuit patterns as a layout pattern. In other embodiments, the SRAF layout patterns do not to overlap the circuit layout patterns. In some embodiments, the mask drawing data is the combination, for example, the logical OR, of the SRAF layout pattern and the circuit layout pattern.

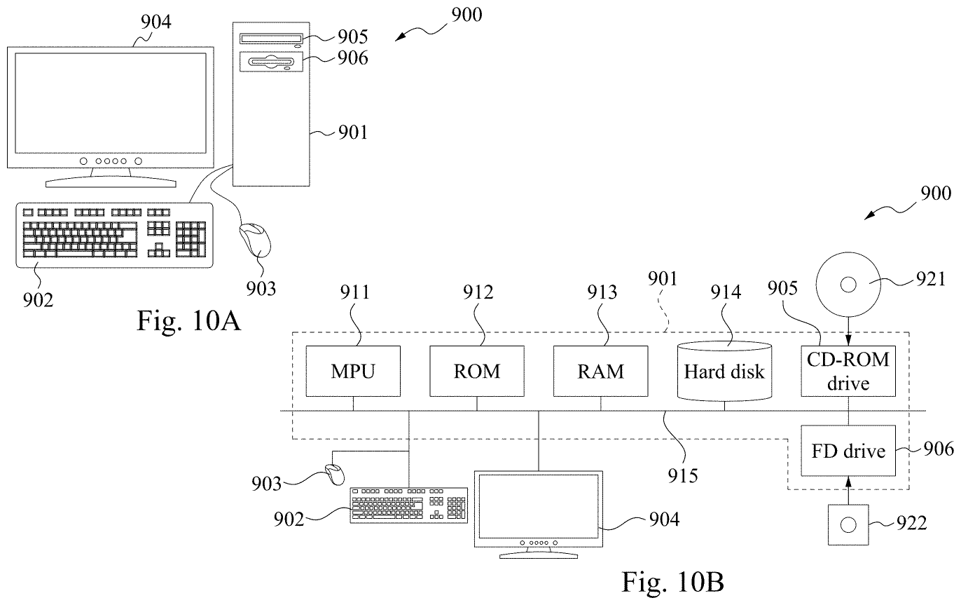

The SRAF patterns are generated by a photo mask data generating apparatus shown in FIGS. 10A and 10B. FIG. 10A is a schematic view of a computer system that executes the photo mask data generating process according to one or more embodiments as described above. All of or a part of the process, method and/or operations of the foregoing embodiments can be realized using computer hardware and computer programs executed thereon. In FIG. 10A, a computer system 900 is provided with a computer 901 including an optical disk read only memory (e.g., CD-ROM or DVD-ROM) drive 905 and a magnetic disk drive 906, a keyboard 902, a mouse 903, and a monitor 904.

FIG. 10B is a diagram showing an internal configuration of the computer system 900. In FIG. 10B, the computer 901 is provided with, in addition to the optical disk drive 905 and the magnetic disk drive 906, one or more processors 911, such as a micro processing unit (MPU), a ROM 912 in which a program such as a boot up program is stored, a random access memory (RAM) 913 that is connected to the MPU 911 and in which a command of an application program is temporarily stored and a temporary storage area is provided, a hard disk 914 in which an application program, a system program, and data are stored, and a bus 915 that connects the MPU 911, the ROM 912, and the like. Note that the computer 901 may include a network card (not shown) for providing a connection to a LAN.

The program for causing the computer system 900 to execute the functions of the photo mask data generating apparatus in the foregoing embodiments may be stored in an optical disk 921 or a magnetic disk 922, which are inserted into the optical disk drive 905 or the magnetic disk drive 906, and transmitted to the hard disk 914. Alternatively, the program may be transmitted via a network (not shown) to the computer 901 and stored in the hard disk 914. At the time of execution, the program is loaded into the RAM 913. The program may be loaded from the optical disk 921 or the magnetic disk 922, or directly from a network.

The program does not necessarily have to include, for example, an operating system (OS) or a third party program to cause the computer 901 to execute the functions of the photo mask data generating apparatus in the foregoing embodiments. The program may only include a command portion to call an appropriate function (module) in a controlled mode and obtain desired results.

In the programs, the functions realized by the programs do not include functions that can be realized only by hardware in some embodiments. For example, functions that can be realized only by hardware, such as a network interface, in an acquiring unit that acquires information or an output unit that outputs information are not included in the functions realized by the above-described programs in some embodiments. Furthermore, a computer that executes the programs may be a single computer or may be multiple computers.

Further, the entirety of or a part of the programs to realize the functions of the photo mask data generating apparatus is a part of another program used for photo mask fabrication processes in some embodiments. In addition, the entirety of or a part of the programs to realize the functions of the photo mask data generating apparatus is realized by a ROM made of, for example, a semiconductor device in some embodiments.

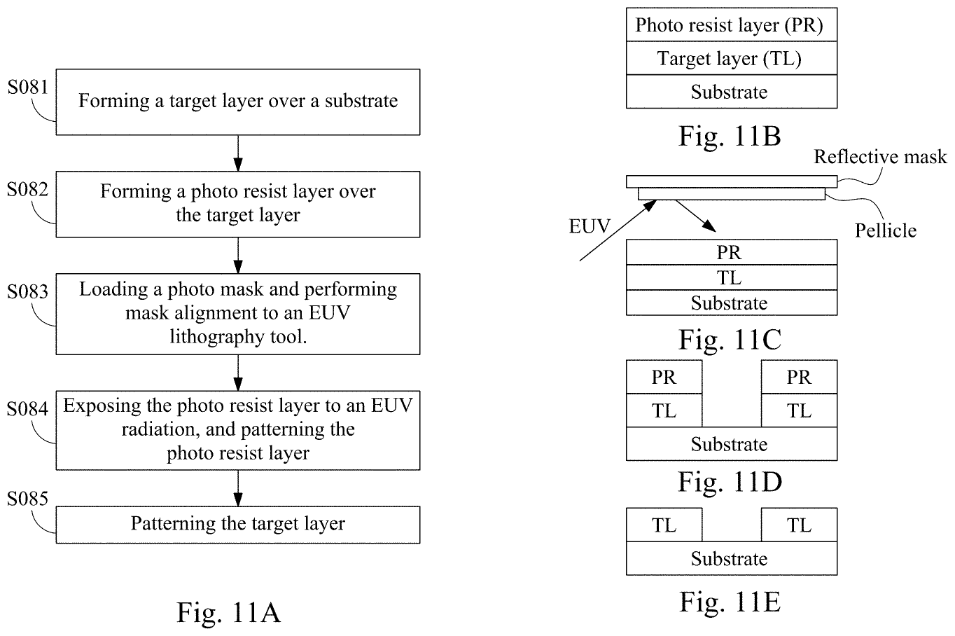

FIG. 11A shows a flowchart of a method of making a semiconductor device, and FIGS. 11B, 11C, 11D and 11E show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 11A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802, of FIG. 11A, a photo resist layer is formed over the target layer, as shown in FIG. 11B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer.

At S803 of FIG. 11A, an EUV photo mask as explained above is loaded into an EUV lithography tool (e.g., EUV scanner) and a mask alignment operation is performed using an alignment system.

At S804 of FIG. 11A, the photo resist layer is patterned using the EUV photo mask, as shown in FIG. 11B. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S805 of FIG. 11A, the target layer is patterned utilizing the patterned photo resist layer as an etching mask, as shown in FIG. 11D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma ashing, as shown in FIG. 11E.

In the present disclosure, the SRAF patterns are provided over or around the circuit patterns of an EUV photo mask, which can suppress the background signal (e.g., undesired EUV reflection). Thus, it is possible to increase a signal contrast (e.g., S/N ratio), and to improve patten accuracy and resolution of the EUV photo mask and to suppress the generation of defects.

It will be understood that not all advantages have been necessarily discussed herein, no particular advantage is required for all embodiments or examples, and other embodiments or examples may offer different advantages.

According to one aspect of the present application, a photo mask for an extreme ultraviolet (EUV) lithography includes a circuit pattern, and sub-resolution assist patterns disposed around and connected to the circuit pattern. A dimension of the sub-resolution assist patterns is in a range from 10 nm to 50 nm. In one or more of the foregoing and following embodiments, the sub-resolution assist patterns include periodic patterns having a pitch equal to or more than 40 nm and less than 160 nm. In one or more of the foregoing and following embodiments, the sub-resolution assist patterns include periodic line patterns having a width in a range from 10 nm to 50 nm and a pitch equal to or more than 40 nm and less than 160 nm. In one or more of the foregoing and following embodiments, the periodic line patterns of the sub-resolution assist patterns are grooves, trenches or openings formed in an absorber layer. In one or more of the foregoing and following embodiments, the circuit pattern includes periodic line patterns having a width greater than the width of the periodic line patterns of the sub-resolution assist patterns. In one or more of the foregoing and following embodiments, the periodic line patterns of the circuit pattern extend in a first direction and arranged in parallel with each other in a second direction crossing the first direction, and the periodic line patterns of the sub-resolution assist patterns extend in the first direction and arranged in parallel with each other in the second direction. In one or more of the foregoing and following embodiments, the periodic line patterns of the circuit pattern extend in a first direction and arranged in parallel with each other in a second direction crossing the first direction, and the periodic line patterns of the sub-resolution assist patterns extend in the second direction and arranged in parallel with each other in the first direction. In one or more of the foregoing and following embodiments, the periodic line patterns of the circuit pattern are grooves, trenches or openings formed in an absorber layer, and the periodic line patterns of the sub-resolution assist patterns are connected to at least one of the periodic line patterns of the circuit pattern.

In accordance another aspect of the present disclosure, a photo mask for an extreme ultraviolet (EUV) lithography includes a substrate, a reflective multilayer structure disposed over the substrate, a capping layer disposed over the reflective multilayer structure, and an absorber layer disposed over the capping layer. The absorber layer has a refractive index equal to or less than 0.95 and an absorption coefficient k equal to or less than 0.04 for an EUV light. The photo mask includes a circuit pattern, and a background intensity suppression pattern disposed around and connected to the circuit pattern having a dimension smaller than a pattern included in the circuit pattern. In one or more of the foregoing and following embodiments, the background intensity suppression pattern comprises grating patterns. In one or more of the foregoing and following embodiments, the circuit pattern includes periodic line patterns, and the background intensity suppression pattern is disposed at least an area between adjacent two line patterns of the circuit pattern. In one or more of the foregoing and following embodiments, the grating patterns include periodic line patterns having a width in a range from 10 nm to 50 nm and a pitch equal to or more than 40 nm and less than 160 nm, and the periodic line patterns of the circuit pattern have a pitch in a range from 3000 nm to 5000 nm and a line width in a range from 100 nm to 300 nm. In one or more of the foregoing and following embodiments, the periodic line patterns of the grating and the circuit pattern are grooves, trenches or openings formed in the absorber layer. In one or more of the foregoing and following embodiments, the grating patterns are non-periodic. In one or more of the foregoing and following embodiments, the background intensity suppression pattern comprises a matrix of square patterns. In one or more of the foregoing and following embodiments, a reflectivity of the absorber layer is equal to or greater than 5%.

In accordance with another aspect of the present disclosure, an attenuated phase shift mask (APSM) for extreme ultraviolet (EUV) lithography, includes a substrate, a reflective multilayer structure disposed over the substrate, a capping layer disposed over the reflective multilayer structure, and an absorber layer disposed over the capping layer. The absorber layer has a reflectivity more than 5% for an EUV light. The APSM includes a circuit pattern to be formed as a photo resist pattern, and sub-resolution assist patterns not to be formed as a photo resist pattern and disposed around circuit pattern. In one or more of the foregoing and following embodiments, a dimension of the sub-resolution assist patterns is in a range from 10 nm to 40 nm, and a refractive index equal to or less than 0.95 and an absorption coefficient k equal to or less than 0.04 for an EUV light. In one or more of the foregoing and following embodiments, the sub-resolution assist patterns include patterns having a pitch equal to or more than 40 nm and less than 160 nm. In one or more of the foregoing and following embodiments, at least one of the sub-resolution assist patterns is connected to the circuit pattern.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photo mask for extreme ultraviolet (EUV) lithography, the photo mask comprising:
a circuit pattern; and
sub-resolution assist patterns disposed around and connected to the circuit pattern, wherein a dimension of the sub-resolution assist patterns is in a range from 10 nm to 50 nm.

2. The photo mask of claim 1, wherein the sub-resolution assist patterns include periodic patterns having a pitch equal to or more than 40 nm and less than 160 nm.

3. The photo mask of claim 1, wherein the sub-resolution assist patterns include periodic line patterns having a width in a range from 10 nm to 50 nm and a pitch equal to or more than 40 nm and less than 160 nm.

4. The photo mask of claim 3, wherein the periodic line patterns of the sub-resolution assist patterns are grooves, trenches or openings formed in an absorber layer.

5. The photo mask of claim 4, wherein the circuit pattern includes periodic line patterns having a width greater than the width of the periodic line patterns of the sub-resolution assist patterns.

6. The photo mask of claim 5, wherein:
the periodic line patterns of the circuit pattern extend in a first direction and are arranged in parallel with each other in a second direction crossing the first direction, and
the periodic line patterns of the sub-resolution assist patterns extend in the first direction and are arranged in parallel with each other in the second direction.

7. The photo mask of claim 5, wherein:
the periodic line patterns of the circuit pattern extend in a first direction and are arranged in parallel with each other in a second direction crossing the first direction, and
the periodic line patterns of the sub-resolution assist patterns extend in the second direction and are arranged in parallel with each other in the first direction.

8. The photo mask of claim 5, wherein:
the periodic line patterns of the circuit pattern are grooves, trenches or openings formed in an absorber layer, and
the periodic line patterns of the sub-resolution assist patterns are connected to at least one of the periodic line patterns of the circuit pattern so as to form a continuous groove, trench or opening.

9. A photo mask for extreme ultraviolet (EUV) lithography, the photo mask comprising:
a substrate;
a reflective multilayer structure disposed over the substrate;
a capping layer disposed over the reflective multilayer structure; and
an absorber layer disposed over the capping layer, wherein:
the absorber layer has a refractive index equal to or less than 0.95 and an absorption coefficient k equal to or less than 0.04 for EUV light, and
the photo mask includes:
a circuit pattern; and
a background intensity suppression pattern disposed around and connected to the circuit pattern having a dimension smaller than a pattern included in the circuit pattern.

10. The photo mask of claim 9, wherein the background intensity suppression pattern comprises grating patterns.

11. The photo mask of claim 10, wherein the circuit pattern includes periodic line patterns, and the background intensity suppression pattern is disposed in at least an area between adjacent two line patterns of the circuit pattern.

12. The photo mask of claim 11, wherein:
the grating patterns include periodic line patterns having a width in a range from 10 nm to 50 nm and a pitch equal to or more than 40 nm and less than 160 nm.

13. The photo mask of claim 12, wherein the periodic line patterns of the grating and the circuit pattern are grooves, trenches or openings formed in the absorber layer.

14. The photo mask of claim 10, wherein the grating patterns are non-periodic.

15. The photo mask of claim 9, wherein the background intensity suppression pattern comprises a matrix of square patterns.

16. The photo mask of claim 9, wherein a reflectivity of the absorber layer is equal to or greater than 5%.

17. An attenuated phase shift mask (APSM) for extreme ultraviolet (EUV) lithography, the APSM comprising:
a substrate;
a reflective multilayer structure disposed over the substrate;
a capping layer disposed over the reflective multilayer structure; and
an absorber layer disposed over the capping layer, wherein:
the absorber layer has a reflectivity of more than 5% for EUV light, and
the APSM includes:
a circuit pattern to be formed as a photo resist pattern; and
sub-resolution assist patterns not to be formed as a photo resist pattern and disposed around circuit pattern.

18. The APSM of claim 17, wherein:
a dimension of the sub-resolution assist patterns is in a range from 10 nm to 40 nm, and
a refractive index equal to or less than 0.95 and an absorption coefficient k equal to or less than 0.04 for an EUV light.

19. The APSM of claim 17, wherein the sub-resolution assist patterns include patterns having a pitch equal to or more than 40 nm and less than 160 nm.

20. The APSM of claim 17, wherein at least one of the sub-resolution assist patterns is connected to the circuit pattern.
